(19) United States
(12) Patent Application Publication
(10) Pub. No.: US 2024/0395448 A1
(43) Pub. Date: Nov. 28, 2024

(54) MAGNETORESISTIVE ELEMENT AND MAGNETIC SWITCH COMPRISING THE MAGNETORESISTIVE ELEMENT

(71) Applicant: Allegro MicroSystems, LLC, Manchester, NH (US)

(72) Inventors: Nikita Strelkov, Meylan (FR); Andrey Timopheev, Vif (FR); Salim Dounia, Grenoble (FR)

(73) Assignee: Allegro MicroSystems, LLC, Manchester, NH (US)

(21) Appl. No.: 18/660,811

(22) Filed: May 10, 2024

(30) Foreign Application Priority Data
May 24, 2023 (EP) 23315217.2

(51) Int. Cl. H01F 10/32; H10N 50/10

(52) U.S. Cl. CPC H01F 10/3254; H10N 50/10

(57) ABSTRACT

Magnetoresistive element comprising a tunnel barrier layer, a ferromagnetic reference layer having a fixed reference magnetization, and a ferromagnetic sense layer having a sense magnetization that can be changed by an external magnetic field (Bext). The reference, tunnel barrier, and sense layers are stacked perpendicular to a layer plane (PL) thereof. At least a portion of the magnetoresistive element comprising the sense layer has a hollow cross-sectional shape in the layer plane (PL), the cross-sectional shape having an outer side with an outer lateral size (Dout) and an inner side defining a width (wd) of the cross-sectional shape. The outer lateral size (Dout) is between 1 μm and 5 μm and the width (wd) is between 0.2 μm and 0.3 μm. The sense magnetization has a coreless vortex configuration and such that the magnetoresistive element has zero remanence at zero external magnetic field (Bext). The present disclosure further concerns a magnetic switch comprising the magnetoresistive element.

### TECHNICAL DOMAIN

The present invention concerns a magnetoresistive element and a magnetic switch comprising the magnetoresistive element.

### RELATED ART

A non-contact type magnetic switch using a tunnel magnetoresistive element are known. In this conventional non-contact type magnetic switch, a permanent magnet is disposed in the vicinity of a magnetoresistive element that exhibits the magnetoresistance effect, and a magnetic field of the permanent magnet acts on the magnetoresistive element. The magnetoresistive element has a lamination structure that is composed of a free layer (free magnetic layer), a non-magnetic layer, a fixed layer (pinned magnetic layer). The fixed layer is magnetized, and the magnetization direction is fixed to a particular direction. On the other hand, the magnetization direction of the free layer is varied by an external magnetic field.

A conventional magnetoresistive-based magnetic switch is usually configured to switch, i.e., to make or break contact, in the presence of an external magnetic field. When the strength of the external magnetic field acting on the magnetoresistive element is varied, the magnetization direction of the free layer is varied relative to the magnetization direction of the fixed layer and the magnitude of the resistance of the magnetoresistive element is thereby varied. The switch operation is performed based on an output signal that reflects a resistance variation of the magnetoresistive element. The switch operation can correspond to the switching between low resistance where the magnetization direction of the free layer is parallel to the magnetization direction of the fixed layer, and a high resistance where the magnetization direction of the free layer is antiparallel to the magnetization direction of the fixed layer. The switch between the low resistive states and high-resistive states occurs for a given magnitude of the external magnetic field (transition field).

Ideally, the low resistive and high-resistive states should be well separated. A conventional magnetoresistive-based magnetic switch is usually configured to switch in the presence of an external magnetic field moderate or weak magnetic field range, for example in the presence of an external magnetic field between 20 mT and 40 mT.

The transition field can be adjusted by modifying the arrangement and/or composition of the layers forming the magnetoresistive element. For example, the transition field can be adjusted by modifying the exchange bias of the sense layer. The transition field can further be modified by using a sense layer comprising a synthetic antiferromagnet with uniaxial magnetic anisotropy, or by using a hard biased sense layer.

However, modifying the arrangement and/or composition of the layers to adjust the transition field also involves separately controlling parameters of the magnetoresistive element, such as the tunnel magnetoresistance, magnetization, magnetic anisotropy, or coupling strength, over a wide range of temperatures. Each parameter that can have its own temperature dependence combines with the other parameters to determine the final properties of the magnetoresistive element. Moreover, the different parameters cannot be controlled independently. For example, the temperature dependence of magnetization, and magnetic anisotropy differs and cannot be controlled separately by modifying the arrangement and/or composition of the layers forming the magnetoresistive element.

### SUMMARY

The present disclosure concerns a magnetoresistive element comprising a tunnel barrier layer sandwiched between a ferromagnetic reference layer having a fixed reference magnetization, and a ferromagnetic sense layer having a sense magnetization that can be oriented in an external magnetic field. The reference, tunnel barrier, and sense layers are stacked perpendicular to a layer plane thereof. At least a portion of the magnetoresistive element comprising the sense layer has a hollow cross-sectional shape in the layer plane, the cross-sectional shape having an outer side with an outer lateral size and an inner side defining a width of the cross-sectional shape. The outer lateral size is between 1 μm and 5 μm and the width is between 0.2 μm and 0.3 μm. The sense magnetization has a coreless vortex configuration and such that the magnetoresistive element has zero remanence at zero external magnetic field.

The present disclosure further concerns a magnetic switch comprising the magnetoresistive element.

The magnetoresistive element disclosed herein allows for obtaining a coreless vortex configuration of the sense magnetization and yields a resistance, or magnetization, hysteresis response that has no remanence at zero field. The resistance hysteresis response thus exhibits a well-defined rectangular-shaped loop that allows for obtaining two well distinguishable high-resistive and low resistive states in the positive magnetic field range. The magnetoresistive element is thus advantageous for a magnetic switch application.

### SHORT DESCRIPTION OF THE DRAWINGS

Exemplar embodiments of the invention are disclosed in the description and illustrated by the drawings in which:

FIG. 1A illustrates a magnetoresistive element comprising a sense layer having a sense magnetization, the sense layer having a cross-sectional shape, according to an embodiment;

FIG. 1B is a top view of the magnetoresistive element of FIG. 1A showing the cross-sectional shape;

FIG. 2 reports the resistance of the magnetoresistive element experimentally measured as a function of the external magnetic field;

FIG. 3 shows simulations of the sense magnetization as a function of the external magnetic field;

FIG. 4 reports a resistance hysteresis response measured on the magnetoresistive element, according to an embodiment;

FIG. 5 shows the simulations of the magnetization hysteresis response for the magnetoresistive element of FIG. 4;

FIGS. 6A to 6E are graphs showing the resistance hysteresis response measured for the magnetoresistive element having a sense layer with a thickness of 19 μm (FIG. 6A), 35 μm (FIG. 6B), 52 μm (FIG. 6C), 68 μm (FIG. 6D), and 85 μm (FIG. 6E);

FIG. 7 reports the expulsion field and nucleation field determined from resistance hysteresis responses measured on the magnetoresistive element, according to an embodiment;

FIG. 8 reports the simulated magnetization hysteresis response, according to an embodiment;

FIG. 9 reports the nucleation field determined from the simulated magnetization hysteresis response of FIG. 8;

FIG. 10 shows a square-shaped cross-sectional shape;

FIG. 11 shows a hexagonal-shaped cross-sectional shape shaped;

FIG. 12A shows the cross-sectional shape comprising two additional geometrical features, according to an embodiment;

FIG. 12B shows the magnetization hysteresis response for the cross-sectional shape of FIG. 12A;

FIG. 13A shows the cross-sectional shape comprising two additional geometrical features, according to another embodiment;

FIG. 13B shows the magnetization hysteresis response for the cross-sectional shape of FIG. 13A;

FIG. 14A shows the cross-sectional shape comprising two additional geometrical features, according to yet another embodiment;

FIG. 14B shows the magnetization hysteresis response for the cross-sectional shape of FIG. 14A;

FIG. 15A shows the cross-sectional shape comprising two additional geometrical features, according to yet another embodiment;

FIG. 15B shows the magnetization hysteresis response for the cross-sectional shape of FIG. 15A;

FIG. 16A shows the cross-sectional shape comprising two additional geometrical features, according to yet another embodiment; and

FIG. 16B shows the magnetization hysteresis response for the cross-sectional shape of FIG. 16A.

### EXAMPLES OF EMBODIMENTS

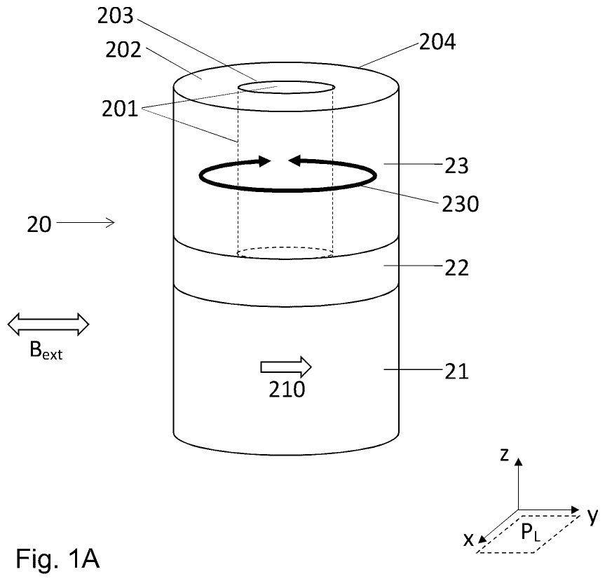

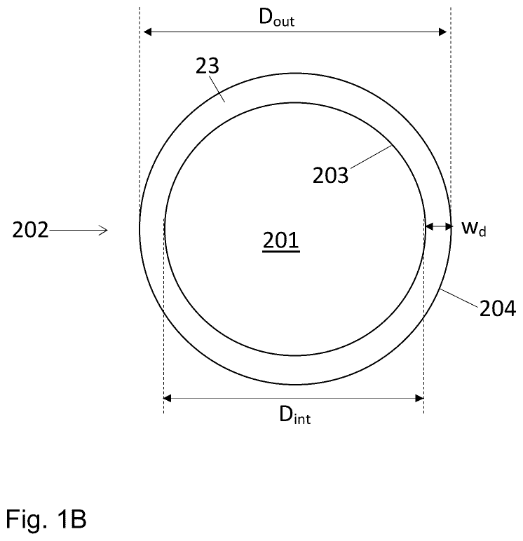

FIG. 1A illustrates a magnetoresistive element 2 according to an embodiment. The magnetoresistive element 2 is based on the tunnel magnetoresistance (TMR) effect and comprises a magnetic tunnel junction 20. In particular, the magnetoresistive element 2 can comprise a tunnel barrier layer 22 sandwiched between a ferromagnetic reference layer 21 and a ferromagnetic sense layer 23. The reference layer 21 has a fixed reference magnetization 210. The sense layer 23 has a sense magnetization 230 that can be changed by an external magnetic field 60. The reference, tunnel barrier, and sense layers 21, 22, 23 extend in a layer plane P_{L} and are stacked perpendicular to the layer plane P_{L}. +

The reference and sense layers 21, 23 can comprise, or can be formed of, a ferromagnetic material such as a cobalt (“Co”), iron (“Fe”) or nickel (“Ni”) based alloy and preferentially a CoFe, NiFe or CoFeB based alloy. The reference layer 21 can have a thickness between 2 nm and 10 nm. The reference and sense layers 21, 23 can comprise a multilayer structure where each layer can include a ferromagnetic material such as a Co, Fe or Ni based alloy and preferentially a CoFe, NiFe or CoFeB based alloy, and non-magnetic layers such as Ta, Ti, W, Ru, Ir. The tunnel barrier layer 22 is a thin layer, typically in the nanometer range and can be formed, for example, from any suitable insulating material, such as alumina (Al₂O₃) or magnesium oxide (MgO).

In the reference: “M. Kläui, et al, “Vortex formation in narrow ferromagnetic rings”, J. Phys. Cond. Matt. 15, R985 (2003)”, the vortex formation in ring-shaped magnetoresistive elements is reported. The ring-shaped magnetoresistive elements can have bistable remanent state in the so-called “onion” magnetic state.

In the present disclosure, it is proposed to use a magnetoresistive element having a ring-shaped configuration and, more generally, a hollow cross-section configuration to obtain a coreless vortex state such that the magnetoresistive element can be switched between two resistive states.

FIG. 1B is a top view of the magnetoresistive element 2 of FIG. 1A, showing the sense layer 23 in the layer plane P_{L}. In the layer plane P_{L}, at least a portion of the magnetoresistive element 2 comprising the sense layer 23 has a hollow cross-sectional shape 202 in the layer plane P_{L} having an inner lateral size Dᵢₙₜ and an exterior part having an outer side 204 with a lateral size Dₒᵤₜ. The hollow cross-sectional shape comprises a hollow center 201. The width w_{d} of the cross-sectional shape 202 corresponds to the difference between the outer lateral size Dₒᵤₜ and the inner lateral size Dᵢₙₜ divided by two (equation 1):

$${w}_{d} = ( Dout - Dint ) / 2. \qquad Eq . 1$$

In the example of FIGS. 1A and 1B, the cross-sectional shape 202 is ring-shaped and the inner lateral size Dᵢₙₜ and the outer lateral size Dₒᵤₜ are, respectively, the inner and outer diameter.

In possible embodiments, the portion of the magnetoresistive element 20 can further comprises the sense layer 23 and the tunnel barrier layer 22. In another aspect, the portion of the magnetoresistive element 20 can comprise the sense layer 23, the tunnel barrier layer 22 and the reference layer 21.

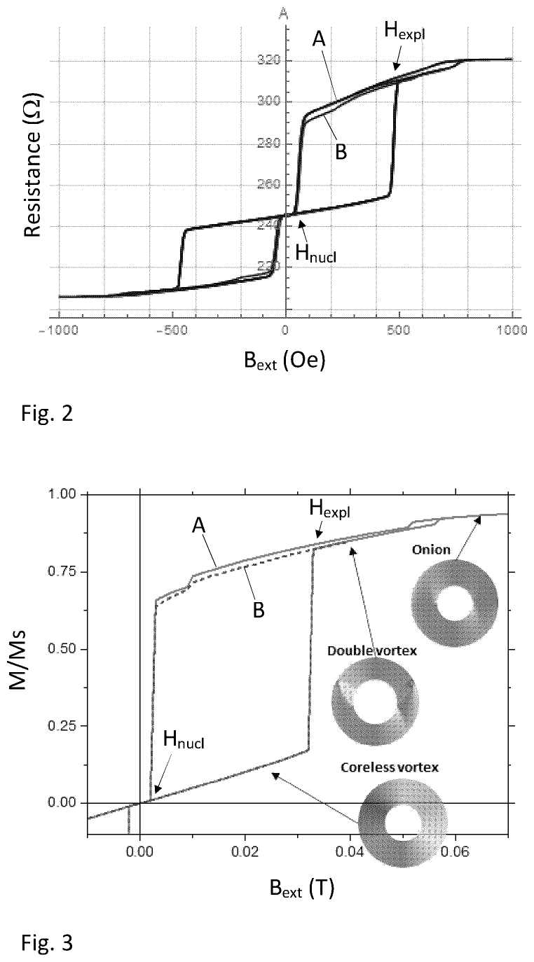

FIG. 2 reports the resistance of the magnetoresistive element 2 experimentally measured as a function of the external magnetic field Bext (hereinafter resistance hysteresis response). The resistance hysteresis response corresponds to the change in resistance of the magnetoresistive element 2 due to the TMR effect. Here, the sense layer 23 is made of NiFe, 52 nm in thickness, and having a cross-sectional shape 202 with an inner diameter of 0.6 μm and an outer diameter of 1 μm (corresponding to a width w_{d} of 0.2 μm). The inventors have found that the above dimensions of the ring-shaped sense layer 23 prevents the nucleation of a vortex core and results in a resistance hysteresis response having no remanence at zero field. The resistance hysteresis response exhibits two rectangular-shaped loops, one in the positive magnetic field range and another in the negative magnetic field range. The higher plateau of the resistance hysteresis response corresponds to the high-resistive state (onion magnetic state). The lower plateau of the resistance hysteresis response corresponds to the low-resistive state (coreless vortex configuration). The expulsion field Hₑₓₚₗ (here at about 450 Oe) corresponds to the transition from the high resistance state to the low resistance state (transition from the onion state to the coreless vortex configuration).

The magnetoresistive element 2 can thus be switched between two resistive states when the external magnetic field Bₑₓₜ is varied between a zero value and a positive value. Due to the well-defined rectangular shape of the loop in the positive magnetic field range, the magnetoresistive element 2 can be switched between two well distinguishable high-resistive and low resistive states (more than about 40Ω in the example of FIG. 2) in the positive magnetic field range. Such behavior of the hysteresis response is useful for a magnetic switch application.

Since the sense magnetization 230 behaves in an isotropic manner, the magnetoresistive element 2 can be used as a magnetic switch to sense transitions at positive and negative the external magnetic field Bₑₓₜ.

FIG. 3 shows the simulations of the sense magnetization 230 as a function of the external magnetic field Bₑₓₜ (a magnetization hysteresis response). The simulations were performed for the magnetoresistive element 2 with the sense layer 23 made of NiFe, 52 nm in thickness, having a cross-sectional shape 202 with an inner diameter of 0.6 μm and an outer diameter of 1 μm. Below the nucleation field H_{nucl}, the sense magnetization 230 has a coreless vortex configuration. Above the expulsion field Hₑₓₚₗ, the magnetization follows the circumference of the ring and forms the so-called ‘onion’ state, or onion configuration, so called as it resembles an onion sliced from top to bottom, which is characterized by two head-to-head domain walls. A transitional magnetic configuration, or “double vortex” configuration, can exist between the onion configuration and the coreless vortex configuration. The coreless vortex configuration is very stable.

In FIGS. 2 and 3, the respectively resistance hysteresis response and magnetization hysteresis response exhibit two well-defined rectangular-shaped loops when the external magnetic field Bₑₓₜ is varied and reaches saturation magnetization, i.e., above the expulsion field Hₑₓₚₗ (major loop) and when the external magnetic field Bₑₓₜ is varied without reaching saturation magnetization (minor loop).

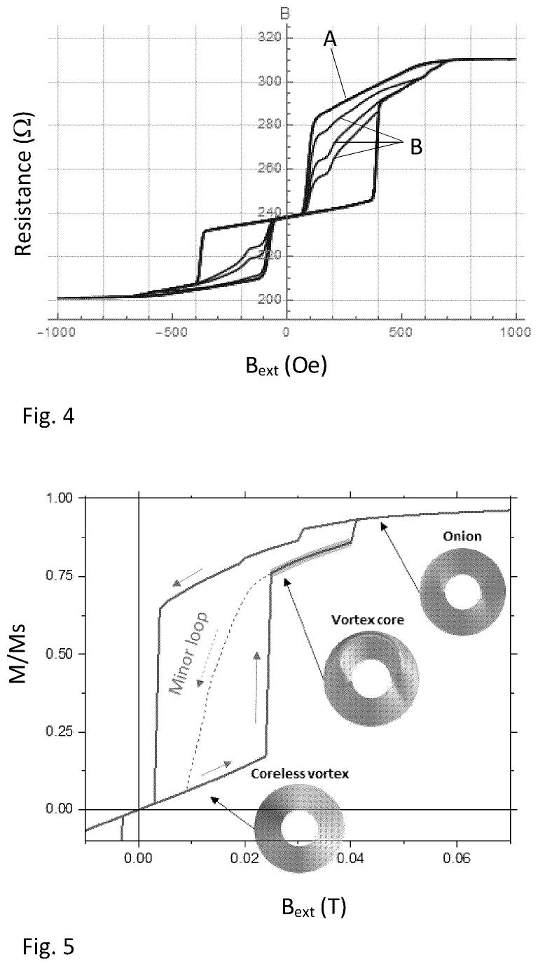

FIG. 4 reports the resistance hysteresis response measured on the magnetoresistive element 2 with the sense layer 23 made of NiFe, 52 nm in thickness, having a cross-sectional shape 202 with an inner diameter of 0.5 μm and an outer diameter of 1 μm (corresponding to a width w_{d} of 0.25 μm). FIG. 5 shows the simulations of the magnetization hysteresis response for the magnetoresistive element 2 measured in FIG. 4. The magnitude of the sense magnetization 230 is substantially the same for the magnetoresistive elements 2 studied in FIGS. 2 to 5.

The resistance hysteresis response exhibits two well-defined rectangular-shaped loops when the external magnetic field Bₑₓₜ is varied such as to reach saturation magnetization (major loop). When the external magnetic field Bₑₓₜ is varied without reaching saturation magnetization (minor loop), the resistance hysteresis response does not exhibit a well-defined rectangular-shaped loop. FIG. 4 shows one major loop (loop A) and three minor loops (loops B). In the case of a minor loop, the sense magnetization 230 forms a vortex core, between magnetic “onion” and coreless vortex states. For the sense layer 23 having an inner diameter of 0.6 nm, i.e., a width w_{d} of 0.2 μm (FIGS. 2 and 3), the minor loops are superimposed and are almost identical to the major loop. The cross-sectional shape 202 of the sense layer 23, i.e., its outer and inner diameter, can thus be tailored to avoid the formation of a vortex core in the sense magnetization 230.

The configuration of the sense magnetization 230, and thus the shape of the resistance hysteresis response of the magnetoresistive element 2, is also influenced by other parameters than the outer Dₒᵤₜ and inner Dᵢₙₜ lateral size. For example, the shape of the resistance hysteresis response can be influenced by the thickness of the sense layer 23.

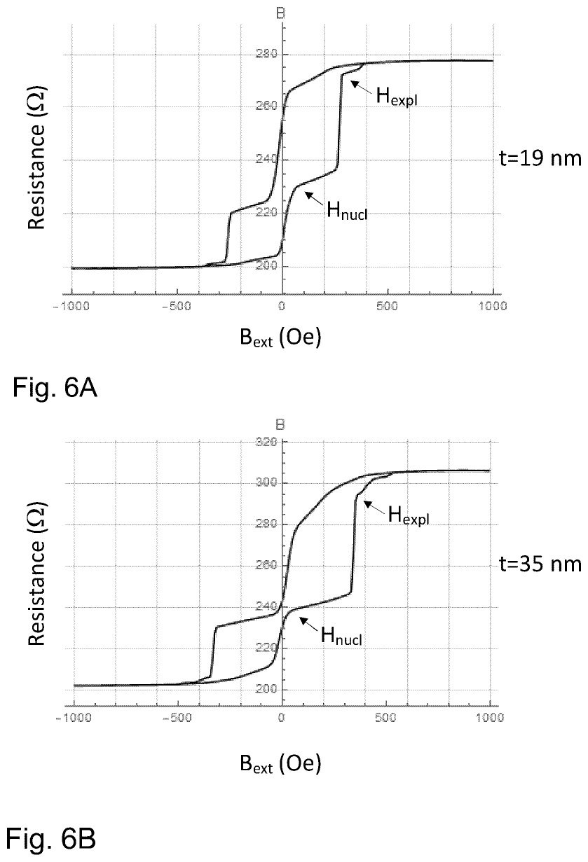

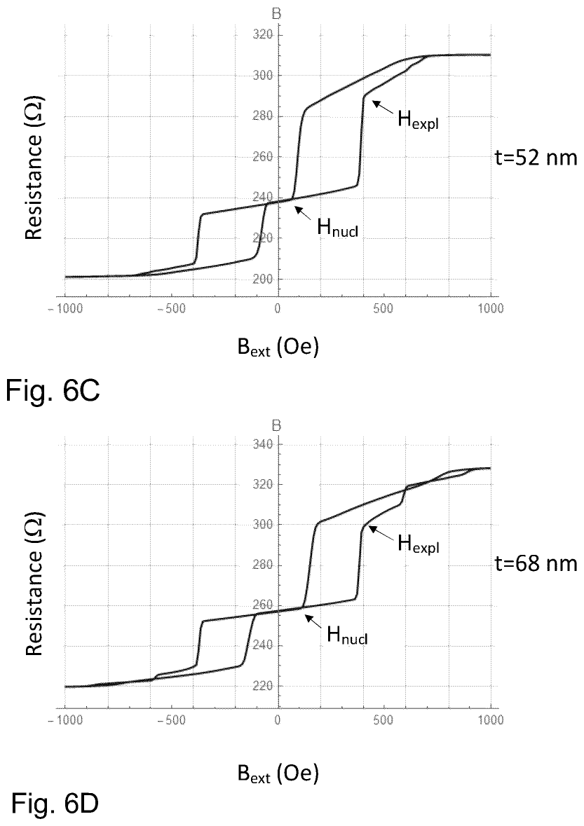

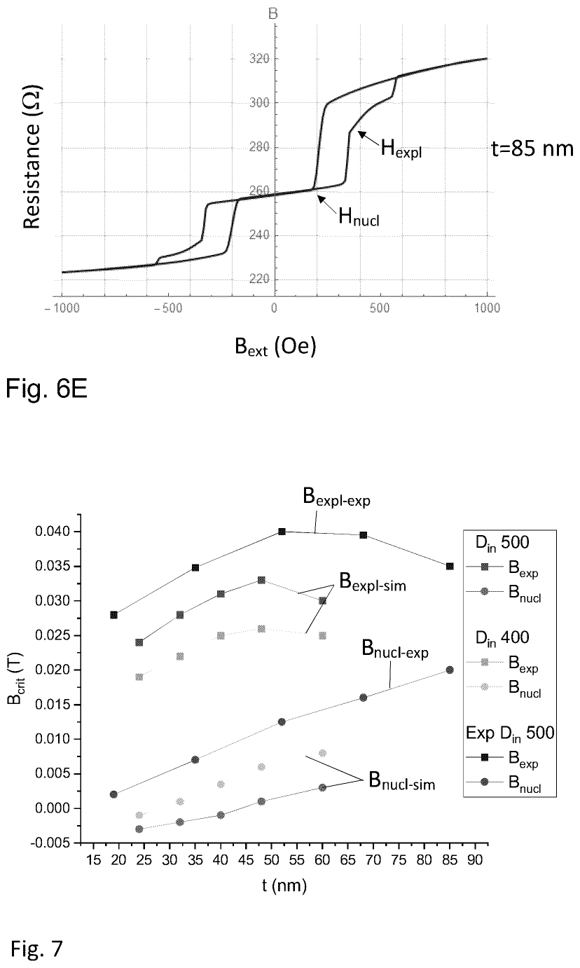

FIGS. 6A to 6E are graphs showing the resistance hysteresis response measured for the magnetoresistive element 2 having a sense layer 23 made of NiFe with a cross-sectional shape having an inner diameter Dᵢₙₜ of 1 μm and an inner diameter of 0.5 μm (width w_{d} of 0.25 μm). More particularly, the resistance hysteresis response was measured for a thickness of the sense layer 23 of 19 μm (FIG. 6A), 35 μm (FIG. 6B), 52 μm (FIG. 6C), 68 μm (FIG. 6D), and 85 μm (FIG. 6E). From FIGS. 6A to 6E, the thicknesses of the sense layer 23 of 52 nm, 68 μm, and 85 μm yield the resistance hysteresis response having no remanence at zero field and exhibiting a rectangular-shaped loop, thus suitable for the magnetoresistive element 2 to be used as a magnetic switch.

FIG. 7 reports the expulsion field Hₑₓₚₗ₋ₑₓₚ and nucleation field H_{nucl-exp} determined from resistance hysteresis responses measured on the magnetoresistive element 2 having a sense layer 23 made of NiFe with a cross-sectional shape 202 of 1 μm outer diameter Dₒᵤₜ and of 0.5 μm inner diameter (width w_{d} of 0.25 μm), for different thickness t of the sense layer 23. FIG. 7 further reports the simulated expulsion field Hₑₓₚₗ₋ₛᵢₘ and nucleation field H_{nucl-sim} for the sense layer 23 made of NiFe with a cross-sectional shape having an outer diameter Dₒᵤₜ of 1 μm and an inner diameter of 0.5 μm and 0.4 μm, as a function of the thickness t of the sense layer 23. In FIG. 7, “B_{crit}” is a critical field that can be either the expulsion field or the nucleation field.

FIG. 7 shows that the measured and simulated nucleation fields H_{nucl-exp}, H_{nucl-sim} increase gradually with the thickness t of the sense layer 23. The measured and simulated expulsion fields Hₑₓₚₗ₋ₑₓₚ, Hₑₓₚₗ₋ₛᵢₘ pass through a maximum for a thickness t of the sense layer 23 that is about 50 nm. These results suggest that the thickness t of the sense layer 23 can be adjusted to maximize the gap between the expulsion field Hₑₓₚₗ and the nucleation field H_{nucl}, such as to obtain well distinguishable high-resistive and low resistive states optimal for magnetic switch applications. The thickness of the sense layer 23 can be further adjusted such that the resistance hysteresis response has no remanence at zero field and the nucleation field H_{nucl} is above zero.

The inventors also found that the shape of the resistance hysteresis response can be influenced by the magnitude of the sense magnetization 230. More particularly, the expulsion field Hₑₓₚₗ can be modified by varying the sense magnetization 230, for example by diluting the sense magnetization 230. Since the exchange stiffness decreases with the magnetization, the nucleation field H_{nucl} does not significantly vary with varying the sense magnetization 230.

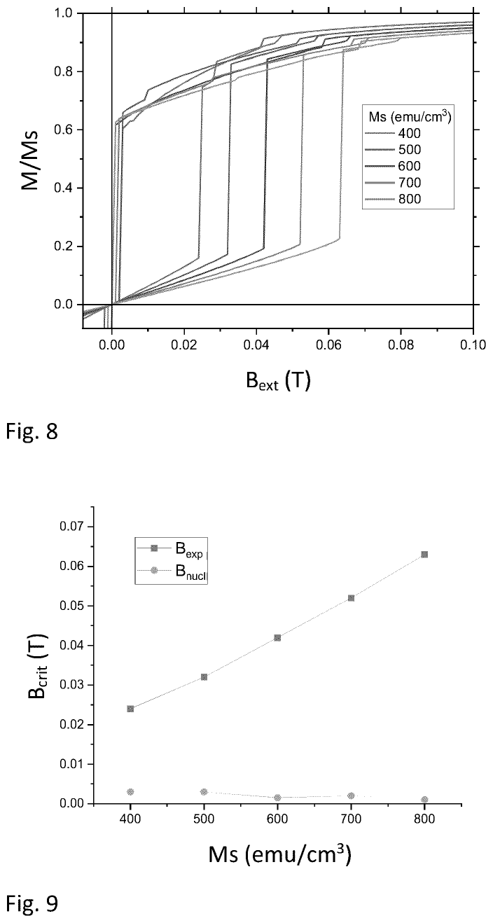

FIG. 8 reports the simulated magnetization hysteresis response, i.e., the magnitude Mₛ of the sense magnetization 230 as a function of the external magnetic field Bₑₓₜ. The simulations were performed for the magnetoresistive element 2 with a NiFe sense layer 23 having an inner diameter of 0.5 μm and outer diameter of 1 μm (width of 0.25 μm). The sense magnetization 230 is varied between 400 and 800 emu/cm³ (4×10⁵ and 8×10⁵ A/m). The dependence of exchange stiffness Aₑ_{^{x}} on the magnetization of NiFe sense layer 23 is considered in the simulations. As shown in FIG. 9, the nucleation field H_{nucl}, determined from the simulated magnetization hysteresis response, is almost constant within the magnetization range 400 and 800 emu/cm³. The expulsion field Hₑₓₚₗ increases monotonically with the magnetization Mₛ. FIGS. 8 and 9 show that adjusting the sense magnetization 230 allows for increasing the expulsion field Hₑₓₚₗ and thus increasing the difference between the high-resistive and low resistive states.

### Dimensions

The present inventors have shown that with the sense layer 23 having a hollow cross-sectional shape 202 with the outer side 204 having a lateral size Dₒᵤₜ between 1 μm and 5 μm and the width w_{d} of the cross-sectional shape 202 between 0.2 μm and 0.3 μm, the sense magnetization 230 can have a closed flux path configuration without vortex core (“coreless vortex” configuration). The coreless vortex configuration is orientable either in the clockwise or counterclockwise direction. The coreless vortex configuration can further be stabilized at zero field, i.e., have zero remanence at zero external magnetic field.

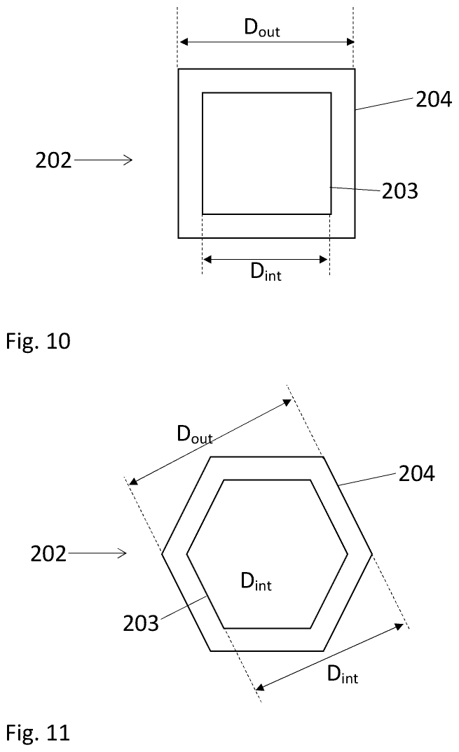

The cross-sectional shape 202 is not limited to a ring shape as exemplified in FIGS. 1A and 1B. In some embodiments, the inner side 203 and outer side 204 of the cross-sectional shape 202 is square shaped (see FIG. 10) or hexagonal shaped (see FIG. 11). Other geometries of the cross-sectional shape 202 are possible (circular, elliptical, rectangular or other polygonal shape, etc.). The inner and outer sides 203, 204 can further have different combinations of geometries. For example, the inner side 203 can be circular and the outer side 204 can be hexagonal.

The transition field for high-resistive and low resistive states can be in part adjusted by modifying the arrangement and/or composition of the layers forming the magnetoresistive element and in part by modifying the lateral dimensions of the cross-sectional shape 202. For example, a lithographic mask can be provided with selected lateral dimensions of the cross-sectional shape 202 and the thickness of the sense layer 23, or the magnitude of the sense magnetization 230, can then be adjusted to tune the transition field. This approach facilitates the design and can lower the manufacturing costs of the magnetoresistive element 2. The magnetoresistive element 2 has low sensitivity to a magnetic field that is below the transition field. The magnetoresistive element 2 can further achieve a reproducible magnetization hysteresis response for a wide range of temperatures and magnetic fields.

### Additional Geometrical Feature

In some embodiments, the cross-sectional shape 202 of the magnetoresistive element 2 can comprise an additional geometrical feature configured to improve the resistance hysteretic response. For example, the additional geometrical feature can be configured to impede the formation of a vortex core in the sense magnetization 230.

In one aspect, the additional geometrical feature comprises cuts, cut-outs or notches provided at symmetrical positions on the inner or outer diameter Dᵢₙₜ, Dₒᵤₜ of the cross-sectional shape 202 of the magnetoresistive element 2. For instance, the cuts, cut-outs or notches can be provided on the cross-sectional shape 202 at locations where a vortex core is likely to appear.

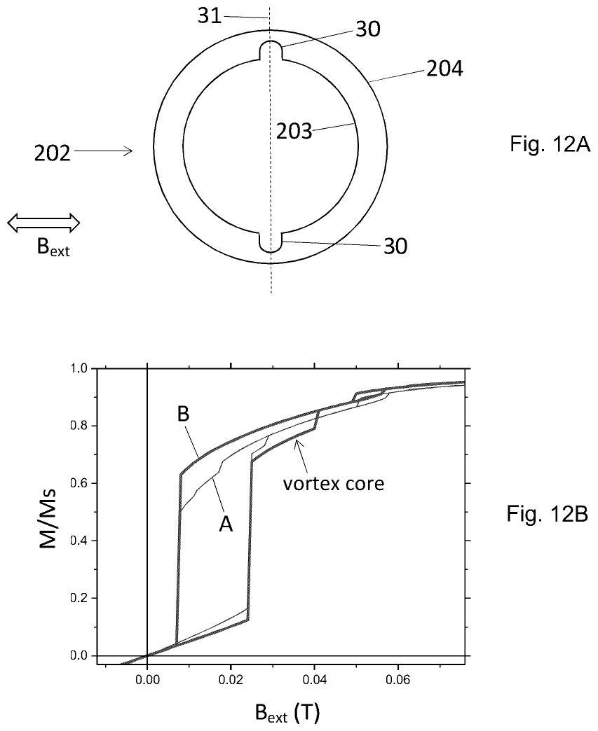

FIGS. 12A to 16B show the simulated magnetization hysteresis response of the magnetoresistive element 2 with the sense layer 23 is made of NiFe, and has a thickness of 60 nm and a magnitude of the sense magnetization 230 of 5×10⁵ A/m. The cross-sectional shape 202 is annular and has an outer diameter of 1 μm and an inner diameter of 0.4 μm (width of 0.2 μm).

More particularly, FIG. 12A shows the cross-sectional shape 202 comprising two additional geometrical features 30, each comprising a notch arranged diametrically opposed on the inner side 203. The corresponding magnetization hysteresis response for the cross-sectional shape 202 of FIG. 12A (curve A) is shown in FIG. 12B. Also show in FIG. 12B is the magnetization hysteresis response corresponding to the cross-sectional shape 202 in the absence of the two additional geometrical features 30 (curve B).

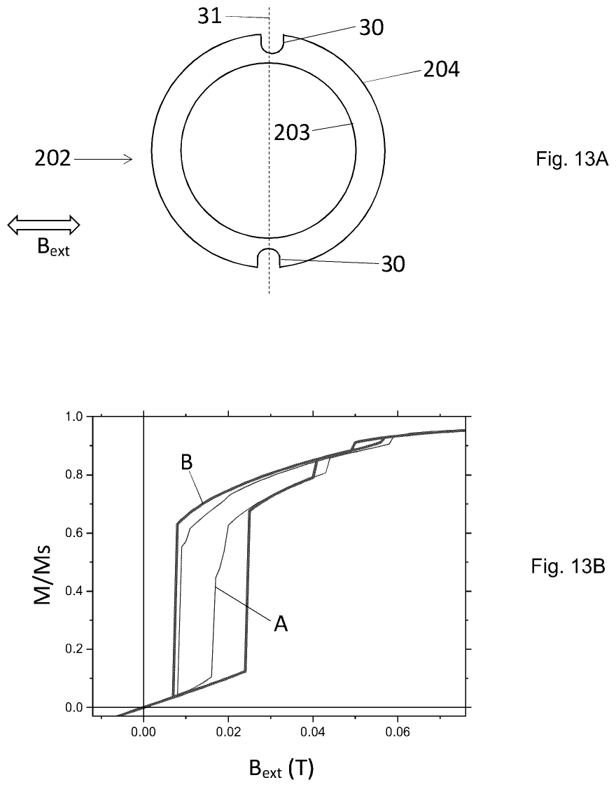

According to a variant, FIG. 13A shows the cross-sectional shape 202 comprising two additional geometrical features 30, each comprising a notch arranged diametrically opposed on the outer side 204. The corresponding magnetization hysteresis response for the cross-sectional shape 202 of FIG. 13A (curve A) is shown in FIG. 13B. Also show in FIG. 13B is the magnetization hysteresis response corresponding to the cross-sectional shape 202 in the absence of the two additional geometrical features 30 (curve B).

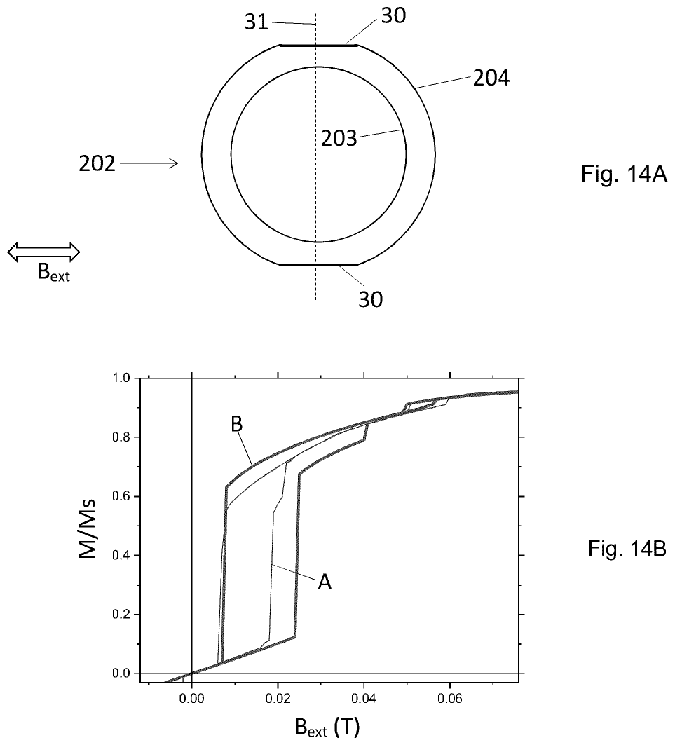

According to another variant, FIG. 14A shows the cross-sectional shape 202 comprising two additional geometrical features 30, each comprising a cut, of flat portion, arranged diametrically opposed on the outer side 204. The corresponding magnetization hysteresis response for the cross-sectional shape 202 of FIG. 14A (curve A) is shown in FIG. 14B. Also shown in FIG. 14B is the magnetization hysteresis response corresponding to the cross-sectional shape 202 in the absence of the two additional geometrical features 30 (curve B).

In the variants of FIGS. 12A, 13A, and 14A, the two additional geometrical features 30 are preferably arranged substantially on the cross-sectional shape 202 along an axis 31 that is substantially perpendicular to the direction of the external magnetic field Bₑₓₜ.

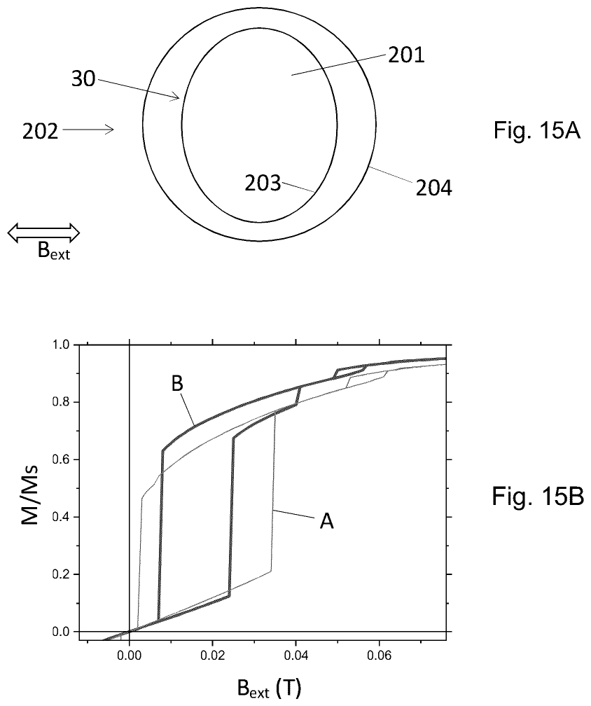

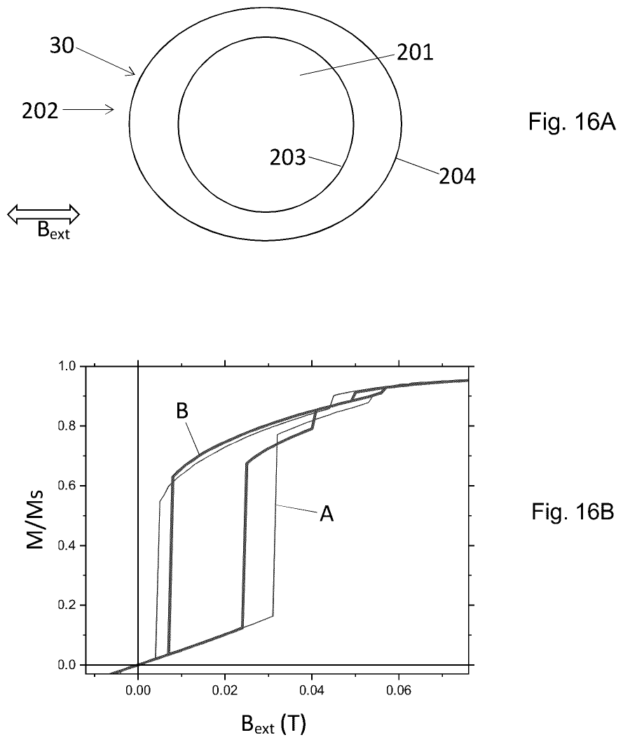

FIGS. 15A, 15B, 16A and 16B show the simulated magnetization hysteresis response of the magnetoresistive element 2 with the sense layer 23 is made of NiFe, and has a thickness of 60 nm and a magnitude of the sense magnetization 230 of 5×10⁵ A/m. In the particular example of FIG. 15A, the cross-sectional shape 202 has a circular-shaped outer side 204 having an outer diameter of 1 μm. The additional geometrical features 30 comprises the inner side 203 having an ellipsoid shape. The corresponding magnetization hysteresis response for the cross-sectional shape 202 of FIG. 15A (curve A) is shown in FIG. 15B. Also shown in FIG. 15B is the magnetization hysteresis response corresponding to the cross-sectional shape 202 in the absence of the two additional geometrical features 30 (curve B).

In another particular example of FIG. 16A, the cross-sectional shape 202 has a circular-shaped inner side 203 having an outer diameter of 0.4 μm. The additional geometrical features 30 comprises the outer side 204 having an ellipsoid shape. The corresponding magnetization hysteresis response for the cross-sectional shape 202 of FIG. 16A (curve A) is shown in FIG. 16B. Also shown in FIG. 16B is the magnetization hysteresis response corresponding to the cross-sectional shape 202 in the absence of the two additional geometrical features 30 (curve B).

FIGS. 15B and 16B show that in the case of the magnetoresistive element where the additional geometrical feature 30 comprises the ellipsoidal outer side 204 or ellipsoidal inner side 203 yields a magnetization hysteresis response with larger area than the magnetization hysteresis response without the additional geometrical feature 30.

The cross-sectional shape 202 of the magnetoresistive element 2 that comprises the additional geometrical feature allows for reducing the vortex core region (indicated in FIG. 12B) generating the undesired minor loop.

The additional geometrical feature 30 can have different geometrical shapes including circular, ellipsoidal, or polygonal cut-outs. The additional geometrical feature 30 should be configured to locally reduce the width w_{d} of the of the cross-sectional shape 202 (without additional geometrical feature 30) by a factor that can be between 20% and 705 or less than 50%. The local reduction of the width w_{d} of the of the cross-sectional shape 202 allows for avoiding the formation of a vortex core and thus, obtaining a well-defined rectangular shape of the magnetization hysteresis response. The additional geometrical feature 30 allows for varying the nucleation and expulsion fields H_{nucl}, Hₑₓₚₗ with zero remanence at zero field.

Preferably, the additional geometrical feature 30 is arranged symmetrically with respect to the center of the cross-sectional shape 202. Preferably, the additional geometrical feature 30 is also arranged substantially perpendicular to the direction of the external magnetic field Bₑₓₜ.

By adapting the geometry of a ring-shaped magnetic magnetoresistive element, nucleation/expulsion transition fields can occur at desired fields with zero remanence at zero field.

Reference numbers and symbols

| | |
|---|---|
| 10 | numbers and symbols |
| | magne to resistive sensor device |
| 11 | first electrical connector |
| 12 | second electrical connector |
| 13 | via |
| 2 | magnetoresistive element |
| 20 | magnetic tunnel junction |
| 201 | interior center |
| 202 | cross-sectional shape |
| 203 | inner side |
| 204 | outer side |
| 21 | reference layer |
| 210 | reference magnetization |
| 211 | first reference sublayer |
| 212 | second reference sublayer |
| 213 | coupling layer |
| 22 | tunnel barrier layer |
| 23 | sense layer |
| 230 | sense magnetization |
| 30 | additional geometrical feature |
| 31 | axis |
| Bₑₓₜ | external magnetic field |
| Dᵢₙₜ | inner lateral size, inner diameter |
| Dₒᵤₜ | outer lateral size, outer diameter |
| P_{L} | layer plane |
| W_{d} | width |

1. Magnetoresistive element comprising:
a tunnel barrier layer sandwiched between a ferromagnetic reference layer having a fixed reference magnetization, and a ferromagnetic sense layer having a sense magnetization that can be changed by an external magnetic field (Bₑₓₜ);
wherein the reference, tunnel barrier, and sense layers are stacked perpendicular to a layer plane (P_{L}) thereof;
characterized in that
at least a portion of the magnetoresistive element comprising the sense layer has a hollow cross-sectional shape in the layer plane (P_{L}), the cross-sectional shape having an outer side with an outer lateral size (Dₒᵤₜ) and an inner side defining a width (w_{d}) of the cross-sectional shape;
wherein the outer lateral size (Dₒᵤₜ) is between 1 μm and 5 μm and the width (w_{d}) is between 0.2 μm and 0.3 μm; such that the sense magnetization has a coreless vortex configuration and such that the magnetoresistive element has zero remanence at zero external magnetic field (Bₑₓₜ).

2. The magnetoresistive element according to claim 1,
wherein the cross-sectional shape is ring-shaped and the inner lateral size (Dᵢₙₜ) and the outer lateral size (Dₒᵤₜ) are, respectively, the inner and outer diameters of the inner and outer sides.

3. The magnetoresistive element according to claim 1,
wherein at least one of the inner side and outer side has a polygonal shape with a number of polygonal sides less or equal to eight.

4. The magnetoresistive element according to claim 3,
wherein the geometry of the inner side differs from the geometry of the outer side of the cross-sectional shape.

5. The magnetoresistive element according to claim 1,
wherein the width (w_{d}) of the cross-sectional shape is constant.

6. The magnetoresistive element according to claim 1,
wherein the cross-sectional shape comprises an additional geometrical feature configured to locally reduce the width (w_{d}) of the of the cross-sectional shape by less than 50%, such as to avoid the formation of a vortex core in the sense magnetization.

7. The magnetoresistive element according to claim 6,
wherein the additional geometrical feature is arranged symmetrically with respect to the center of the cross-sectional shape.

8. The magnetoresistive element according to claim 6,
wherein the additional geometrical feature is arranged substantially perpendicular to the direction of the external magnetic field (Bₑₓₜ).

9. The magnetoresistive element according to claim 6,
wherein the cross-sectional shape comprises two additional geometrical features, each comprising a notch arranged diametrically opposed on the inner side or on the outer side.

10. The magnetoresistive element according to claim 6,
wherein the cross-sectional shape comprises two additional geometrical features, each comprising a cut, of flat portion, arranged diametrically opposed on the outer side.

11. The magnetoresistive element according to claim 6,
wherein the additional geometrical features comprises the inner side having an ellipsoid shape and the outer side having a circular shape; or
the outer side having an ellipsoid shape and the inner side having a circular shape.

12. A magnetic switch comprising the magnetoresistive element according to claim 1.
